(19) United States
(12) Patent Application Publication
(10) Pub. No.: US 2024/0425968 A1
(43) Pub. Date: Dec. 26, 2024

(54) Method for Solvent Free Perovskite Deposition

(71) Applicant: CubicPV Inc., Bedford, MA (US)

(72) Inventors: Michael D. Irwin, Heath, TX (US); Marissa Higgins, Forney, TX (US); David W. Miller, Dallas, TX (US)

(21) Appl. No.: 18/828,935

(22) Filed: Sep. 9, 2024

Related U.S. Application Data
(62) Division of application No. 16/852,142, filed on Apr. 17, 2020, now Pat. No. 12,116,663.
(60) Provisional application No. 62/836,376, filed on Apr. 19, 2019.

(51) Int. Cl. C23C 14/08; C23C 14/24; C23C 14/32; C23C 14/34; C23C 14/50

(52) U.S. Cl. CPC C23C 14/088; C23C 14/243; C23C 14/325; C23C 14/3407; C23C 14/50

(57) ABSTRACT

A method for solvent-free perovskite deposition. The method comprises loading a lead target and one or more samples adhered to a substrate holder into a deposition chamber, pumping down to a high vacuum pressure, and backfilling the deposition chamber with the vapor of a salt precursor to form a perovskite material.

### CROSS REFERENCE TO RELATED APPLICATION

This application is a divisional application of U.S. patent application Ser. No. 16/852,142, filed on Apr. 17, 2020, which claims priority to U.S. Patent Application No. 62/836,376 filed on Apr. 19, 2019, all of which are incorporated herein by reference in their entireties.

### TECHNICAL FIELD

This application relates generally to compositions for use in photovoltaic and optoelectronic devices, and more particularly to methods for solvent-free perovskite deposition.

### BACKGROUND

Use of photovoltaics (PVs) to generate electrical power from solar energy or radiation may provide many benefits, including, for example, a power source, low or zero emissions, power production independent of the power grid, durable physical structures (no moving parts), stable and reliable systems, modular construction, relatively quick installation, safe manufacture and use, and good public opinion and acceptance of use.

Perovskite materials may be incorporated into one or more aspects of a PV device. PVs using perovskite components are more tolerant of internal defects than silicon-based PVs. This greater tolerance reduces the cost of production. However, the traditional, solvent-based methods of manufacturing perovskite cells can lead to uneven thickness across a layer. This limits the ability to effectively coat large surfaces and to generate efficient multi-stack films.

The features and advantages of the present disclosure will be readily apparent to those skilled in the art. While numerous changes may be made by those skilled in the art, such changes are within the spirit of the invention.

### SUMMARY OF THE DISCLOSURE

According to one embodiment, a method for solvent-free perovskite deposition comprises loading a lead target and a substrate into a deposition chamber. The method further comprises reducing the pressure in the deposition chamber to less than or equal to 5×10⁻⁶ Torr. The method further comprises vaporizing the lead target. Further still, the method comprises backfilling the deposition chamber with the vapors of a salt precursor. Finally, the method comprises depositing a perovskite material on the substrate.

In another embodiment, a method for solvent-free perovskite deposition comprises loading a lead powder sample into a crucible. The method further comprises placing a substrate face-down over the powder in the crucible. The method further comprises reducing the pressure in the deposition chamber to 200 mTorr. The method further comprises sublimating the lead powder sample. Finally, the method comprises making a first deposition on the substrate.

In a further embodiment, a method for solvent-free perovskite deposition comprises loading a lead salt precursor into a crucible. The method further comprises loading a substrate into a sample holder. The method further comprises reducing the pressure in the deposition chamber to at least 10⁻³ Torr. The method further comprises applying a current to ionize the lead salt precursor. The method further comprises backfilling the deposition chamber with the vapors of a second salt precursor. Finally, the method comprises depositing a perovskite material on the substrate.

In yet another embodiment, a method for solvent-free perovskite deposition comprises loading a lead salt precursor into a crucible. The method further comprises loading a substrate in a sample holder. The method further comprises reducing the pressure in the deposition chamber to between 5 Torr and 760 torr. The method further comprises vaporizing the lead salt precursor. The method further comprises performing metalorganic vapor phase epitaxy on the vapor. The method further comprises backfilling the deposition chamber with the vapors of a second salt precursor. Finally, the method comprises depositing, under an inert gas, a perovskite material on the substrate.

### BRIEF DESCRIPTION OF THE DRAWINGS

FIG. 1 is a flowchart for an example method of solvent-free perovskite deposition.

### DETAILED DESCRIPTION OF PREFERRED EMBODIMENTS

The methods described in the present disclosure for depositing perovskite onto a substrate may be used to manufacture one or more aspects of a PV. Other potential applications include, but are not limited to, batteries, field-effect transistors (FETs), light-emitting diodes (LEDs), non-linear optical devices, memristors, capacitors, rectifiers, and/or rectifying antennas. A perovskite material may be of the general formula CMX₃, where: C comprises one or more cations (e.g., an amine, ammonium, phosphonium, a Group 1 metal, a Group 2 metal, and/or other cations or cation-like compounds); M comprises one or more metals (examples including Be, Mg, Ca, Sr, Ba, Fe, Cd, Co, Ni, Cu, Ag, Au, Hg, Sn, Ge, Ga, Pb, In, Tl, Sb, Bi, Ti, Zn, Cd, Hg, and Zr); and X comprises one or more anions. In particular embodiments, C may comprise formamidinium or methylammonium. While many of the methods described below are illustrated using lead perovskite, these methods may be used to achieve other perovskites by substituting the desired metal (M) or metal halide (MXₙ).

In some embodiments, the present disclosure provides methods of depositing perovskite based on physical vapor deposition. In further embodiments, the present disclosure provides methods of depositing perovskite based on chemical vapor deposition. Several embodiments of physical vapor and chemical vapor deposition methods are described in detail below.

In each of the embodiments described below, patterning of the resulting perovskite film may be achieved by placing a tight-fitting shadow mask directly over the substrate prior to loading the substrate into the vacuum chamber.

### Physical Vapor Deposition Methods

Generally, physical vapor deposition involves vaporizing the deposition material, transporting the vapor to the target substrate, reaction between the metal atoms and a reactive gas during the transport stage, and deposition at the substrate. The present disclosure includes several embodiments of physical vapor deposition. Specifically, methods for sputtering, reactive sputtering, electron beam deposition, cathodic arc deposition, pulsed laser deposition, molecular beam epitaxy, close space sublimation, thermal evaporation and co-evaporation with annealing, vapor-assisted solution processing, ion assisted deposition, and activated reactive evaporation are described.

### Sputtering

In certain embodiments, a method for solvent-free perovskite deposition comprises loading a PbI₂ (lead (II) iodide) target into a sputtering chamber and pumping down to high-ultra high vacuum pressure. For example, the pressure should be pumped down to less than or equal to 10⁻⁶ Torr. Preferably, systems should be under static vacuum of 10⁻⁸ torr. The method further comprises loading samples adhered to a substrate holder into a load-lock chamber. The method further comprises pumping the load-lock chamber to a high vacuum (10⁻³ to 10⁻⁵ Torr) and transferring a sample holder into the sputtering chamber. In some embodiments the high vacuum may be less than 1×10⁻⁵ Torr. The method further comprises applying an inert gas, such as Ar, to the PbI₂ target to induce a sputtering effect, backfilling the sputtering chamber with FAI (formamidinium iodide) and/or MAI (methyl ammonium iodide) vapor, and depositing a perovskite material. The chamber may be backfilled using a mass flow controller (MFC) at a rate between 2-100 sccm. In some embodiments the FAI and/or MAI may be introduced at a rate between 5-30 sccm. The method contemplates the first 20 nm of perovskite should be deposited at a rate of approximately 0.5 Å/second to ensure the material is adhered to a substrate.

In other embodiments, a method for solvent-free perovskite deposition comprises loading a Pb (lead) target into a sputtering chamber and pumping down to high-ultra high vacuum pressure. For example, the pressure should be pumped down to less than or equal to 10⁻⁶ Torr. Preferably, systems should be under static vacuum of 10⁻⁸ torr. The method further comprises loading samples adhered to a substrate holder into a load-lock chamber. The method continues with pumping down the load-lock chamber to high vacuum pressure (10⁻³ to 10⁻⁵ Torr) and transferring a sample holder into the load-lock chamber. The method further comprises applying an inert gas, such as Ar, to the Pb target to induce a sputtering effect, backfilling the chamber with HI (hydrogen iodide) and one or both of FAI or MAI vapor, and depositing a perovskite material. The chamber may be backfilled using an MFC at a rate between 2-100 sccm. In some embodiments the HI and one or both of MAI or FAI may be introduced at a rate between 5-30 sccm. The method contemplates the first 20 nm of perovskite should be deposited at a rate of approximately 0.5 Å/second to ensure the material is adhered to a substrate.

In yet another embodiment, a method for solvent-free perovskite material deposition comprises loading a Pb target (either Pb with HI, or PbI₂) into a sputtering chamber and pumping down to high-ultra high vacuum pressure. For example, the pressure should be pumped down to less than or equal to 10⁻⁶ Torr. Preferably, systems should be under static vacuum of 10⁻⁸ torr. The method further comprises loading a sample adhered to a substrate holder into a load-lock chamber and pump down the load-lock chamber to high vacuum pressure (10⁻³ to 10⁻⁵ Torr) before transferring a sample holder into the chamber. The method continues with applying an inert gas, such as Ar, to the PbI₂ target to induce a sputtering effect, backfilling the chamber with HI, and depositing a perovskite material. Backfilling of the chamber may be accomplished using an MFC at a rate between 2-100 sccm. In some embodiments the HI may be introduced at a rate between 5-30 sccm. The method contemplates the first 20 nm of perovskite should be deposited at a rate of approximately 0.5 Å/second to ensure the material is adhered to a substrate. The method concludes with removing the PbI₂ film from the chamber and transferring the film to a different instrument, such as a thermal evaporator, for the deposition of FAI and/or MAI.

### Reactive Sputtering

In other embodiments, a method for solvent-free perovskite material deposition comprises loading a PbI₂ target into a sputtering chamber and pumping down to high-ultra high vacuum pressure. For example, the pressure should be pumped down to less than or equal to 10⁻⁶ Torr. Preferably, systems should be under static vacuum of 10⁻⁸ torr. The method further comprises loading samples adhered to a substrate holder into the sputtering chamber. The method further comprises pumping a load-lock chamber to high vacuum pressure (10⁻³ to 10⁻⁵ Torr) and transferring a sample holder into the load-lock chamber. The method further comprises applying a reactive gas, such as oxygen or nitrogen, to the PbI₂ target to induce a sputtering effect, backfilling the chamber with FAI and/or MAI vapor, and depositing a perovskite material. The chamber may be backfilled using an MFC at a rate between 2-100 sccm. In some embodiments the FAI and/or MAI may introduced at a rate between 5-30 sccm. The method contemplates the first 20 nm of perovskite should be deposited at a rate of approximately 0.5 Å/second to ensure the material is adhered to a substrate.

In other embodiments, a method for solvent-free perovskite material deposition comprises loading a Pb (lead) target into a sputtering chamber and pumping down to high-ultra high vacuum pressure. For example, the pressure should be pumped down to less than or equal to 10⁻⁶ Torr. Preferably, systems should be under static vacuum of 10⁻⁸ torr. The method further comprises loading samples adhered to a substrate holder into a load-lock chamber. The method continues with pumping the load-lock chamber to high vacuum pressure (10⁻³ to 10⁻⁵ Torr) and transferring a sample holder into the load-lock chamber. The method further comprises applying a reactive gas, such as oxygen or nitrogen, to the Pb target to induce a sputtering effect, backfilling the chamber with HI (hydrogen iodide) and one or both of FAI or MAI vapor and depositing a perovskite material. The chamber may be backfilled using an MFC at a rate between 2-100 sccm. In some embodiments the HI and one or both of MAI or FAI may be introduced at a rate between 5-30 sccm. The method contemplates the first 20 nm of perovskite should be deposited at a rate of approximately 0.5 Å/second to ensure the material is adhered to a substrate.

In yet another embodiment, a method for solvent-free perovskite material deposition comprises loading a Pb target into a sputtering chamber and pumping down to high-ultra high vacuum pressure. For example, the pressure should be pumped down to less than or equal to 10⁻⁶ Torr. Preferably, systems should be under static vacuum of 10⁻⁸ torr. The method further comprises loading a sample adhered to a substrate holder into a load-lock chamber and pumping the load-lock chamber to high vacuum pressure (10⁻³ to 10⁻⁵ Torr) before transferring a sample holder into the chamber. The method continues with applying a reactive gas, such as oxygen or nitrogen, to the Pb target to induce a sputtering effect, backfilling the chamber with HI, and depositing a perovskite material. The chamber may be backfilled using an MFC at a rate between 2-100 sccm. In some embodiments the HI may be introduced at a rate between 5-30 sccm. The method contemplates the first 20 nm of perovskite should be deposited at a rate of approximately 0.5 Å/second to ensure the material is adhered to a substrate. The method concludes with removing the PbI₂ film from the chamber and transferring the film to a different instrument, such as a thermal evaporator, for the deposition of FAI and/or MAI.

### Electron Beam Physical Vapor Depositions or Electron Beam Depositions

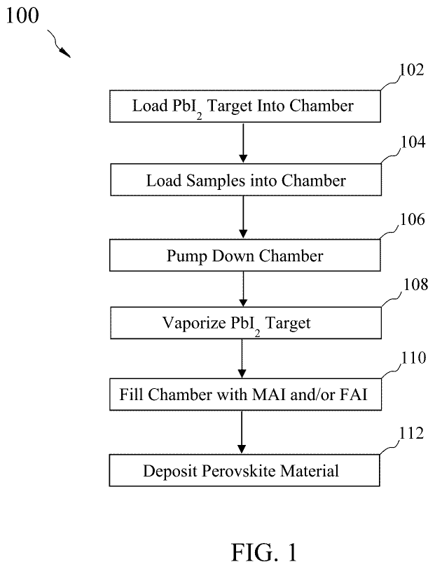

FIG. 1 illustrates a method 100 for solvent-free perovskite material deposition. Step 102 comprises loading a PbI₂ target into a deposition chamber. Step 104 comprises loading samples adhered to the substrate holder into the deposition chamber. The method 100 continues at step 106 with pumping down to a high vacuum pressure (less than or equal to 5×10⁻⁶ Torr). At step 108, an electron beam is applied to the PbI₂ target. The method 100 then proceeds to step 110 where the deposition chamber is backfilled with FAI and/or MAI vapor. The chamber may be backfilled using an MFC at a rate between 2-100 sccm. In some embodiments the FAI and/or MAI may be introduced at a rate between 5-30 sccm. Finally, the example method concludes at step 112 by depositing a perovskite material. The method contemplates the first 20 nm of perovskite should be deposited at a rate of approximately 0.5 Å/second to ensure the material is adhered to a substrate.

In other embodiments, a method for solvent-free perovskite material deposition comprises loading a Pb target into a deposition chamber and loading samples adhered to a substrate holder into the deposition chamber. The method further comprises pumping down to a high vacuum pressure (less than or equal to 5×10⁻⁶ Torr) and applying an electron beam to the Pb target. The method continues with backfilling the chamber with HI and formamidine and/or methylamine (MA) vapor and depositing a perovskite material. The chamber may be backfilled using an MFC at a rate between 2-100 sccm. In some embodiments the HI and FA and/or MA may be introduced at a rate between 5-30 sccm. The method contemplates the first 20 nm of perovskite should be deposited at a rate of approximately 0.5 Å/second to ensure the material is adhered to a substrate.

In yet another embodiment, a method for solvent-free perovskite material deposition comprises loading a Pb target into a deposition chamber and loading samples adhered to a substrate holder into the deposition chamber. The method further comprises pumping down to a high vacuum pressure (less than or equal to 5×10⁻⁶ Torr) and applying an electron beam to the Pb target. The method continues with backfilling the chamber with HI vapor and depositing a perovskite material. The chamber may be backfilled using an MFC at a rate between 2-100 sccm. In some embodiments the HI may be introduced at a rate between 5-30 sccm. The method concludes with removing the PbI₂ film from the chamber and transferring the film to a different instrument, such as a thermal evaporator, for the deposition of FAI and/or MAI. The method contemplates the first 20 nm of perovskite should be deposited at a rate of approximately 0.5 Å/second to ensure the material is adhered to a substrate.

### Cathodic Arc Physical Vapor Depositions

In certain embodiments, a method for solvent-free perovskite material deposition comprises loading a Pb target into a deposition chamber and loading samples adhered to a substrate holder into the deposition chamber. The method further comprises pumping down to ultra-high vacuum pressure (10⁻⁸ to 10⁻¹² Torr) and applying a cathodic arc to the Pb target. The method continues with backfilling the chamber with HI vapor and depositing a perovskite material. The chamber may be backfilled using an MFC at a rate between 2-100 sccm. In some embodiments the HI may be introduced at a rate between 5-30 sccm. The method concludes with removing the PbI₂ film from the chamber and transferring the film to a different instrument, such as a thermal evaporator, for the deposition of FAI and/or MAI. The method contemplates the first 20 nm of perovskite should be deposited at a rate of approximately 0.5 Å/second to ensure the material is adhered to a substrate.

### Pulsed Laser Depositions

In certain embodiments, a method for solvent-free perovskite material deposition comprises loading a PbI₂ target into a deposition chamber and loading samples adhered to a substrate holder into the deposition chamber. The method further comprises pumping down to high vacuum pressure (10⁻⁶ to 10⁻⁸ Torr) and applying a pulsed laser to the PbI₂ target. The method continues with backfilling the chamber with FAI and/or MAI vapor and depositing a perovskite material. The chamber may be backfilled using an MFC at a rate between 2-100 sccm. In some embodiments the FAI and/or MAI may be introduced at a rate between 5-30 sccm. The method contemplates the first 20 nm of perovskite should be deposited at a rate of approximately 0.5 Å/second to ensure the material is adhered to a substrate.

In other embodiments, a method for solvent-free perovskite material deposition comprises loading a Pb target into a deposition chamber and loading samples adhered to a substrate holder into the deposition chamber. The method further comprises pumping down to high vacuum pressure (10⁻⁶ to 10⁻⁸ Torr) and applying a pulsed laser to the Pb target. The method continues with backfilling the chamber with HI and one or both of MAI or FAI vapor and depositing a perovskite material. The chamber may be backfilled using an MFC at a rate between 2-100 sccm. In some embodiments the HI and one or both of MAI or FAI may be introduced at a rate between 5-30 sccm. The method contemplates the first 20 nm of perovskite should be deposited at a rate of approximately 0.5 Å/second to ensure the material is adhered to a substrate.

In yet another embodiment, a method for solvent-free perovskite material deposition comprises loading a Pb target into a deposition chamber and loading samples adhered to a substrate holder into the deposition chamber. The method further comprises pumping down to high vacuum pressure (10⁻⁶ to 10⁻⁸ Torr) and applying a pulsed laser to the Pb target. The method continues with backfilling the chamber with HI vapor and depositing a perovskite material. The chamber may be backfilled using an MFC at a rate between 2-100 sccm. In some embodiments the HI may be introduced at a rate between 5-30 sccm. The method concludes with removing the PbI₂ film from the chamber and transferring the film to a different instrument, such as a thermal evaporator, for the deposition of FAI and/or MAI. The method contemplates the first 20 nm of perovskite should be deposited at a rate of approximately 0.5 Å/second to ensure the material is adhered to a substrate.

### Molecular Beam Epitaxy

In certain embodiments, a method for solvent-free perovskite material deposition comprises loading a Pb target into a deposition chamber and loading samples adhered to a substrate holder into the deposition chamber. The method further comprises pumping down to ultra-high vacuum pressure (10⁻⁸ to 10⁻¹² Torr) and applying a molecular beam to the Pb target. The method continues with backfilling the chamber with HI vapor and depositing a perovskite material. The chamber may be backfilled using an MFC at a rate between 2-100 sccm. In some embodiments the HI may be introduced at a rate between 5-30 sccm. The method concludes with removing the PbI₂ film from the chamber and transferring the film to a different instrument, such as a thermal evaporator, for the deposition of FAI and/or MAI. The method contemplates the first 20 nm of perovskite should be deposited at a rate of approximately 0.5 Å/second to ensure the material is adhered to a substrate.

### Close Space Sublimation

In certain embodiments, a method for solvent-free perovskite material deposition comprises loading a PbI₂ powder sample into a crucible and placing the substrate over the sample, face down. The method further comprises pumping down to a low vacuum pressure (˜200 mTorr) and sublimating the PbI₂ powder sample. The method continues with backfilling a chamber with FAI and/or MAI vapor and depositing a perovskite material. The chamber may be backfilled using an MFC at a rate between 2-100 sccm. In some embodiments the FAI and/or MAI may be introduced at a rate between 5-30 sccm. The method contemplates the first 20 nm of depositions should be made at a rate of approximately 0.5 Å/second to ensure the material is adhered to a substrate.

In other embodiments, a method for solvent-free perovskite material deposition comprises loading a Pb powder sample into a crucible and covering the crucible with the Pb powder sample face down. The method further comprises pumping down to low vacuum pressure (˜200 mTorr), sublimating the Pb sample, and making a first deposition. The method continues with backfilling a chamber with HI and one or both of formylimidamide (FA) or methylamine (MA) vapor and making a second deposition. The chamber may be backfilled using an MFC at a rate between 2-100 sccm. In some embodiments the HI and one or both of MA or FA may be introduced at a rate between 5-30 sccm. The method contemplates the first 20 nm of depositions should be made at a rate of approximately 0.5 Å/second to ensure the material is adhered to a substrate.

In yet another embodiment, a method for solvent-free perovskite material deposition comprise loading a PbI₂ powder sample into a crucible and covering the crucible with the PbI₂ powder sample face down. The method further comprises pumping down to low vacuum pressure (˜200 mTorr), sublimating the PbI₂ powder sample, and making a first deposition. The method further comprises replacing the PbI₂ powder sample with MAI and/or FAI powder samples and placing the MAI and/or FAI powder samples face down over the crucible. The method concludes with pumping down to a pressure of 200 mTorr, sublimating the MAI and/or powder samples, and making a second deposition. The method contemplates the first 20 nm of depositions should be made at a rate of approximately 0.5 Å/second to ensure the material is adhered to a substrate.

In a further embodiment, a method for solvent-free perovskite deposition comprises growing a single crystal perovskite with the structure ABX₃ by any method known to those skilled in the art. The method further comprises loading a single crystal into a crucible and loading the substrate face down into the substrate holder. Depending on the size of the crystals, it may be necessary to crush the crystal perovskite into more uniform pieces with a mortar and pestle. The method further comprises pumping down to low vacuum pressure (˜200 mTorr), sublimating the crystal, and making a first deposition.

Thermal Evaporating and Co-Evaporation with Annealing

In certain embodiments, a method for solvent-free perovskite material deposition comprises loading a PbI₂ powder sample into a crucible and loading substrates on a sample holder. The method further comprises pumping down to high vacuum pressure (less than or equal to 5×10⁻⁶ Torr) and evaporating the PbI₂ powder sample by applying a voltage between two metal posts. The method continues with backfilling a chamber with FAI and/or MAI vapor and making depositions. The chamber may be backfilled using an MFC at a rate between 2-100 sccm. In some embodiments the FAI and/or MAI may be introduced at a rate between 5-30 sccm. The method contemplates the first 20 nm of depositions should be made at a rate of approximately 0.5 Å/second to ensure the material is adhered to a substrate.

In other embodiments, a method for solvent-free perovskite material deposition comprises loading a PbI₂ powder sample into a first crucible and loading MAI and/or FAI samples into a second crucible. The method further comprises loading substrates on a sample holder and pumping down to a high vacuum pressure (less than or equal to 5×10⁻⁶ Torr). The method continues with evaporating the PbI₂ and the MAI and/or FAI samples by applying a voltage between two metal posts, and depositing PbI₂ and MAI and/or FAI at the same time. The method contemplates the first 20 nm of depositions should be made at a rate of approximately 0.5 Å/second to ensure the material is adhered to a substrate.

In yet another embodiment, a method for solvent-free perovskite material deposition comprises loading a Pb sample into a crucible, loading substrates on a sample holder, and pumping down to high vacuum pressure (less than or equal to 5×10⁻⁶ Torr). The method further comprises evaporating the Pb sample by applying a voltage between two metal posts. The method continues with backfilling the chamber with HI and one or both of FAI or MAI vapor and making depositions. The chamber may be backfilled using an MFC at a rate between 2-100 sccm. In some embodiments the HI and one or both of MAI or FAI may be introduced at a rate between 5-30 sccm. The method contemplates the first 20 nm of depositions should be made at a rate of approximately 0.5 Å/second to ensure the material is adhered to a substrate.

In further embodiments, a method for solvent-free perovskite material deposition comprises loading a PbI₂ powder sample into a crucible, loading substrates on a sample holder, and pumping down to high vacuum pressure (less than or equal to 5×10⁻⁶ Torr). The method further comprises evaporating the PbI₂ powder sample by applying a voltage between two metal posts and making a first deposition. The method continues with replacing the PbI₂ powder sample with a MAI and/or FAI powder sample and pumping down to high vacuum pressure (less than or equal to 5×10⁻⁶ Torr). The method concludes by evaporating the MAI and/or FAI powder sample by applying a voltage between two metal posts and making a second deposition. The method contemplates the first 20 nm of depositions should be made at a rate of approximately 0.5 Å/second to ensure the material is adhered to a substrate.

In yet other embodiments, a method for solvent-free perovskite material deposition comprises growing a single crystal perovskite with the structure ABX₃ by any method. The method further comprises loading the single crystal(s) into a crucible. In some instances, it may be necessary to crush the crystal(s) in a mortar and pestle to achieve more uniform, smaller pieces. The method further comprises loading samples into a substrate holder. The method further comprises pumping down the deposition chamber to high vacuum pressure (less than or equal to 5×10⁻⁶ Torr). The method concludes by applying a voltage to two metal posts connected to the precursor crucible to evaporate the crystal(s), and making a deposition on the sample.

### Vapor-Assisted Solution Processing or Hybrid Physical Chemical Deposition

In certain embodiments, a method for solvent-free perovskite material deposition comprises depositing a layer of PbI₂ onto a film by any of the above disclosed methods. The PbI₂ film may be patterned with the use of a tight-fitting shadow mask. The method further comprises placing the film with the PbI₂ layer face up in a reduced pressure chamber (between 200 mTorr and 10⁻⁶ Torr) and introducing hydrogen iodide (HI) vapor. The method concludes with flowing methylamine (MA) and/or formylimidamide (FA) vapor, which may exist as its tautomer formamidine in the gas phase, into the reduced pressure chamber. The MA and/or FA vapor may be introduced using an MFC at a rate between 2-100 sccm. In some embodiments it may be introduced at a rate between 5-30 sccm.

In certain embodiments, a method for solvent-free perovskite material deposition comprises depositing a layer of HPbI₃ onto a film by any of the above disclosed methods. The method further comprises placing the film with the HPbI₃ layer face up in a reduced pressure chamber. The method concludes with flowing methylamine (CH₃NH₂) and/or formylimidamide (NH₂CHNH) vapor into the reduced pressure chamber. Alternatively, methylamine (CH₃NH₂) and/or formylimidamide (NH₂CHNH) vapor is added to PbI₂ first, and then followed by HI.

### Thermal Spraying (Spray Coating)

In certain embodiments, a method for solvent-free perovskite material deposition comprises spraying a PbI₂ sample, heated to 20-80° C., onto a film at atmospheric pressure and placing the film with the PbI₂ layer face up in a reduced pressure chamber (between 200 mTorr and 10⁻⁶ Torr). The method concludes with flowing MA and/or FA vapor into the reduced pressure chamber. The MA and/or FA vapor may be introduced using an MFC at a rate between 2-100 sccm. In some embodiments it may be introduced at a rate between 5-30 sccm.

### Ion Plating or Ion Assisted Deposition

In certain embodiment, a method for solvent-free perovskite material deposition comprises loading a Pb target into a deposition chamber, loading samples adhered to a substrate holder into the deposition chamber, and pumping down the chamber to less than or equal to 10⁻⁵ Torr. In some embodiments, the chamber is pumped down to 10⁻⁸ Torr. The method further comprises evaporating the Pb target by striking the source material with a bombardment of particles. Vaporization by particle bombardment may be accomplished using evaporation, sputtering, arc vaporization, or chemical means. This form of vaporization requires the addition of inert (e.g., Ar) or reactive (e.g., O₂ or N₂) gas. The method further comprises backfilling the chamber with HI vapor and making depositions. The chamber may be backfilled using an MFC at a rate between 2-100 sccm. In some embodiments the HI may be introduced at a rate between 5-30 sccm. The method concludes with removing the PbI₂ film from the chamber and transferring the film to a different instrument, such as a thermal evaporator, for the deposition of FAI and/or MAI. The method contemplates the first 20 nm of depositions should be made at a rate of approximately 0.5 Å/second to ensure the material is adhered to a substrate.

### Activated Reactive Evaporation

In certain embodiments, a method for solvent-free perovskite material deposition comprises loading a PbI₂ target into a deposition chamber, loading samples adhered to a substrate holder into the deposition chamber, and pumping down to a high vacuum pressure (less than or equal to 5×10⁻⁶ Torr). The method further comprises evaporating the PbI_{b} target in the presence of a reactive gas and a plasma. The method continues with backfilling the chamber with FAI and/or MAI vapor and making depositions. The chamber may be backfilled using an MFC at a rate between 2-100 sccm. In some embodiments the FAI and/or MAI may be introduced at a rate between 5-30 sccm. The method contemplates the first 20 nm of depositions should be made at a rate of approximately 0.5 Å/second to ensure the material is adhered to a substrate.

In other embodiments, a method for solvent-free perovskite material deposition comprises loading a Pb target into a deposition chamber, loading samples adhered to a substrate holder into the deposition chamber, and pumping down to a high vacuum pressure (less than or equal to 5×10⁻⁶ Torr). The method further comprises evaporating the Pb target in the presence of a reactive gas and a plasma. The method continues with backfilling the chamber with HI and one or both of MAI or FAI vapor and making depositions. The chamber may be backfilled using an MFC at a rate between 2-100 sccm. In some embodiments the HI and one or both of MAI or FAI may be introduced at a rate between 5-30 sccm. The method contemplates the first 20 nm of depositions should be made at a rate of approximately 0.5 Å/second to ensure the material is adhered to a substrate.

In yet another embodiment, a method for solvent-free perovskite material deposition comprises loading a Pb target into a deposition chamber, loading samples adhered to a substrate holder into the deposition chamber, and pumping down to a high vacuum pressure (less than or equal to 5×10⁻⁶ Torr). The method further comprises evaporating the Pb target in the presence of a reactive gas and a plasma. The method continues with backfilling the chamber with HI vapor and making depositions. The chamber may be backfilled using an MFC at a rate between 2-100 sccm. In some embodiments the HI may be introduced at a rate between 5-30 sccm. The method concludes with removing the PbI₂ film from the deposition chamber and transferring the film to a different instrument, such as a thermal evaporator, for the deposition of FAI and/or MAI. The method contemplates the first 20 nm of depositions should be made at a rate of approximately 0.5 Å/second to ensure the material is adhered to a substrate.

### Chemical Vapor Deposition

Generally, chemical vapor deposition involves vaporizing a precursor, transporting the vapor to the target substrate, chemical reaction between the precursor vapors and the surface to be coated, and deposition at the substrate. Various precursors may be used with each of the chemical vapor deposition methods described below. Possible lead precursors generally include lead alkoxides, lead alkylamides, lead alkylsulfides, lead alkylselenides, plumbanes, and plumbylenes. In some embodiments the lead precursor may be bis(1-dimethylaminio-2-methyl-2-propanolate)lead (II) (Pb(DMAMP)₂); bis(2,2,6,6-tetramethyl-3,5,heptanedionato)lead(II) (Pb(THD)₂); lead(II) hexafluoroacetylacetonate; plumbocene (PbCp₂); tetraethyllead(IV); bis[bis(trimethylsilyl)amido] lead(II); or rac-N²,N³-di-tert-butane-2,3-diamido lead (II). Possible iodine precursors generally include metal iodides and alkylammonium iodide salts. In some embodiments the iodine precursor may be trimethylsilyl iodide (TMSI); iodine (I₂); hydrogen iodide (HI); hydroiodic acid; tin (IV) iodide; or methylammonium iodide. Possible formamidinium iodide precursors generally include formamidinium salts, formamidinium precursor reagents (formates, imidic esters, triazines), ammonium salts, and cyanide salts. In some embodiments the formamidinium precursor may be formamidinium iodide (FAI); formamidinium acetate; triethoxyl orthoformate; ethyl methanimidinium iodide; 1,3,5-Triazine; ammonia (NH₃); ammonium iodide (NH₄I); ammonium hydroxide (NH₄OH); or hydrogen cyanide (HCN).

The present disclosure includes several embodiments of physical vapor deposition. Specifically, methods for atomic layer deposition, plasma enhanced chemical vapor deposition, metal-organic vapor phase epitaxy, hydride vapor phase epitaxy, thin-film vapor liquid-solid conversion, and liquid phase epitaxy are described.

### Atomic Layer Deposition

In certain embodiments, a method for solvent-free perovskite material deposition comprises loading a PbI₂ precursor into a deposition chamber and loading a FAI sample into the deposition chamber. The method further comprises pumping down to low vacuum pressure (100-500 mTorr), pulsing a first PbI₂ precursor for at least 0.015 seconds, waiting 10-30 seconds to allow time for a reaction to occur at the substrate, pulsing a second PbI₂ for at least 0.015 seconds, waiting 10-30 seconds to allow time for a reaction to occur at the substrate, and then repeating the cycle until the desired material thickness is achieved. Depositions are made under carrier gas, typically N₂. In certain embodiments, the method requires depositing PbS into a deposition chamber and producing PbI₂ before loading the PbI₂ precursor into the deposition chamber.

For example, after loading a FAI sample into the deposition chamber and pumping down the vacuum to low vacuum pressure, lead (II) acetate is introduced to the chamber, making a first deposition. After waiting 30 seconds, trimethylsilyl iodide is introduced to the chamber, making a second deposition. The second deposition reacts with the first deposition to form a layer of PbI₂. The example method further comprises waiting another 30 seconds before restarting the cycle by introducing lead (II) acetate to the chamber. Lead (II) acetate and trimethylsilyl iodide may be introduced using an MFC at a rate between 2-100 sccm. In some embodiments they may be introduced at a rate between 5-30 sccm.

As another example, after loading the FAI sample into the deposition chamber and pumping down the vacuum to low vacuum pressure, PbS is introduced to the chamber, making a first deposition. After waiting 30 seconds, TMSI is introduced to the chamber, making a second deposition. The second deposition reacts with the first deposition to form a layer of PbI₂. The example method further comprises waiting another 30 seconds before restarting the cycle by introducing PbS. PbS and TMSI may be introduced using an MFC at a rate between 2-100 sccm. In some embodiments they may be introduced at a rate between 5-30 sccm.

In other embodiments, a method for solvent-free perovskite material deposition comprises loading a PbI₂ precursor into a deposition chamber, loading a FAI sample into the deposition chamber, and pumping down to low vacuum pressure (100-500 mTorr). In certain embodiments, the method requires depositing PbS into a deposition chamber and producing PbI₂ before loading the PbI₂ precursor into the deposition chamber. The method further comprises alternating between making PbI₂ precursor depositions and making FAI depositions onto a film. The method concludes with placing the PbI₂ precursor face up in a reduced pressure chamber and flowing MAI and/or FAI vapor into the reduced pressure (between 200 mTorr and 10⁻⁶ Torr) chamber. The MAI and/or FAI vapor may be introduced using an MFC at a rate between 2-100 sccm. In some embodiments it may be introduced at a rate between 5-30 sccm.

For each of the atomic layer deposition methods described above, the substrate may be selectively patterned prior to being placed in the deposition chamber. For example, patterning may be applied using O₂ plasma, ozone cleaning, or other surface modification techniques known to those skilled in the art. Patterning provides selective areas to which nucleation of precursors may adhere.

### Plasma Enhanced Chemical Vapor Deposition

In certain embodiments, a method for solvent-free perovskite material deposition comprises loading a Pb precursor into a crucible, loading substrates on a sample holder, and pumping down to high vacuum pressure (at least 10⁻³ Torr). The method further comprises introducing a reactive gas into the deposition chamber and applying a current to ionize the reactive gas and the Pb precursor. The method concludes with backfilling a chamber with FAI and/or MAI vapor and making depositions. In some embodiments, backfilling also includes introducing reactive gases. Suitable reactive gases, in addition to those already mentioned in this disclosure, include water, oxygen, nitrous oxide, ammonia, and nitrogen. The chamber may be backfilled using an MFC at a rate between 2-100 sccm. In some embodiments the FAI and/or MAI (and reactive gas where appropriate) may be introduced at a rate between 5-30 sccm. The method contemplates the first 20 nm of depositions should be made at a rate of approximately 0.5 Å/second to ensure the material is adhered to a substrate.

In other embodiments, a method for solvent-free perovskite material deposition comprises loading a Pb precursor into a crucible, loading substrates on a sample holder, and pumping down to high vacuum pressure (at least 10⁻³ Torr). The method further comprises applying a current to ionize the Pb precursor. The method continues with backfilling the chamber with HI and one or both of MAI or FAI and making depositions. The chamber may be backfilled using an MFC at a rate between 2-100 sccm. In some embodiments the HI and one or both of MAI or FAI may be introduced at a rate between 5-30 sccm. The method contemplates the first 20 nm of depositions should be made at a rate of approximately 0.5 Å/second to ensure the material is adhered to a substrate.

In yet another embodiment, a method for solvent-free perovskite material deposition comprises loading a PbI₂ precursor into a crucible, loading substrates on the sample holder, and pumping down to a high vacuum pressure (at least 10⁻³ Torr). The method further comprises applying a current to ionize the PbI₂ precursor and making depositions. In some embodiments, reactive gases may be introduced before ionizing the precursor. Any of the previously mentioned reactive gases are suitable. The method continues with transferring the film to an instrument, such as a thermal evaporator, and flowing MA and/or FA vapor into the reduced pressure chamber (between 200 mTorr and 10⁻⁶ Torr). The MA and/or FA vapor may be introduced using an MFC at a rate between 2-100 sccm. In some embodiments it may be introduced at a rate between 5-30 sccm. The method concludes with making MAI and/or FAI depositions.

### Metalorganic Vapor Phase Epitaxy (Metalorganic Chemical Vapor Deposition)

In certain embodiments, a method for solvent-free perovskite material deposition comprises loading a Pb precursor into a crucible, loading substrates on a sample holder, pumping down the chamber to moderate pressure (between 5 Torr and 760 torr), and applying one of heat or a flow of electrons to the Pb precursor create Pb vapor. The method further comprises applying a metalorganic vapor phase epitaxy process to the Pb vapor. The method continues with backfilling a chamber with FAI and/or MAI vapor, and making depositions under an inert carrier gas such as Ar. The chamber may be backfilled using an MFC at a rate between 2-100 sccm. In some embodiments the FAI and/or MAI vapor may be introduced at a rate between 5-30 sccm. The method contemplates the first 20 nm of depositions should be made at a rate of approximately 0.5 Å/second to ensure the material is adhered to a substrate.

In other embodiments, a method for solvent-free perovskite material deposition comprises loading a Pb precursor into a crucible, loading substrates on a sample holder, pumping down the chamber to moderate pressure (between 5 Torr and 760 torr), and applying one of heat or a flow of electrons to the Pb precursor create Pb vapor. The method further comprises applying a metalorganic vapor phase epitaxy process to the Pb vapor. The method continues with backfilling a chamber with HI and one or both of MAI or FAI, and making depositions under an inert carrier gas such as Ar. The chamber may be backfilled using an MFC at a rate between 2-100 sccm. In some embodiments the HI and one or both of MAI or FAI vapor may be introduced at a rate between 5-30 sccm. The method contemplates the first 20 nm of depositions should be made at a rate of approximately 0.5 Å/second to ensure the material is adhered to a substrate.

In yet another embodiment, a method for solvent-free perovskite material deposition comprises loading a Pb precursor into a crucible, loading substrates on a sample holder, and pumping down the chamber to moderate pressure (between 5 Torr and 760 torr). The method further comprises applying one of heat or a flow of electrons to the Pb precursor create Pb vapor. The method further comprises applying a metalorganic vapor phase epitaxy process to the Pb vapor under an inert carrier gas such as Ar. The method continues with transferring the film to an instrument, such as a thermal evaporator, and depositing FAI and/or MAI. The method contemplates the first 20 nm of depositions should be made at a rate of approximately 0.5 Å/second to ensure the material is adhered to a substrate.

In each of the embodiments described above for metalorganic vapor phase epitaxy, the Pb precursor may plumbocene or a plumbylene. Any of the other Pb precursors detailed in this disclosure are also suitable.

### Hydride Vapor Phase Epitaxy

In certain embodiments, a method for solvent-free perovskite material deposition comprises loading a Pb precursor into a crucible, loading substrates on a sample holder, pumping down the chamber to moderate pressure (between 5 Torr and 760 torr), and applying one of heat or a flow of electrons to the Pb precursor create Pb vapor. The method further comprises applying HCl (hydrochloric acid). The method continues with backfilling a chamber with HI and one or both of MAI or FAI vapor and making depositions. The chamber may be backfilled using an MFC at a rate between 2-100 sccm. In some embodiments the HI and one or both of MAI or FAI vapor may be introduced at a rate between 5-30 sccm. Carrier gases are used in some embodiments to facilitate deposition. Suitable carrier gases include NH₃, H₂, and chlorides. The method contemplates the first 20 nm of depositions should be made at a rate of approximately 0.5 Å/second to ensure the material is adhered to a substrate.

In other embodiments, a method for solvent-free perovskite material deposition comprises loading a Pb precursor into a crucible, loading substrates on a sample holder, pumping down the chamber to moderate pressure (between 5 Torr and 760 torr), and applying one of heat or a flow of electrons to the Pb precursor create Pb vapor. The method further comprises applying HCl. The method continues with backfilling a chamber with HI vapor and making depositions to a film. The chamber may be backfilled using an MFC at a rate between 2-100 sccm. In some embodiments the HI may be introduced at a rate between 5-30 sccm. Carrier gases are used in some embodiments to facilitate deposition. Suitable carrier gases include NH₃, H₂, and chlorides. The method concludes with transferring the film to an instrument, such as a thermal evaporator, and depositing FAI and/or MAI.

### Thin-Film Vapor-Liquid-Solid Conversion

In certain embodiments, a method for solvent-free perovskite deposition comprises applying at least one of heat or a flow of electrons to a metal, C (where C is e.g. group I or II cations as listed in the preferred embodiments), M (e.g. Pb, Sn, etc. as described in Preferred Embodiments), or a blend of metals C and M to evaporate the metals onto a substrate. The method further comprises the direct application of the liquid metal C or M, or alloys or compounds thereof (e.g. lead(II) acetate trihydrate). The method continues with heating the substrate and stabilizing the temperature above the melting point of the metal or metal blend. The method further comprises the use of substrate surface treatments and inert porous capping layers to prevent de-wetting of the liquid metal or metals from the substrate. The method continues with application of HX, X₂, and/or CX vapor to the chamber to produce a thin film of the compound CMX₃. In particular embodiments HI, I₂ and/or CsI vapor are applied to the chamber containing a liquid metal film of Pb, Cs, or Cs and Pb to form a thin film of CsPbI₃. In certain embodiments the method further comprises the use of other compounds to stabilize the CX vapor at high temperatures including C decay products in the case that C is an organic cation that may otherwise be unstable at the temperature required to melt the metals C, M or CM alloy. Alternate precursor compounds, for example lead (II) acetate trihydrate, may be used.

### Liquid Phase Epitaxy

Any of the embodiments of thin-film vapor-liquid-solid conversion described above may be executed on a crystalline substrate with the goal of epitaxial growth. In some embodiments, the substrate may be single crystalline perovskite substrates or other lattice matched compounds.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

To aid the Patent Office, and any readers of any patent issued on this application in interpreting the claims appended hereto, applicants note that they do not intend any of the appended claims to invoke 35 U.S.C. § 112(f) as it exists on the date of filing hereof unless the words “means for” or “step for” are explicitly used in the particular claim.

1. A method for solvent-free perovskite deposition, comprising:
loading a lead powder sample into a crucible;
placing a substrate face-down over the powder in the crucible;
reducing the pressure in the deposition chamber to 200 mTorr;
sublimating the lead powder sample;
making a first deposition on the substrate.

2. The method of claim 1, wherein:
the lead powder sample comprises lead (II) iodide;
the method further comprising backfilling the deposition chamber with the vapors of a salt precursor prior to making the first deposit, the salt precursor comprising a salt selected from the group consisting of formamidinium iodide, methyl ammonium iodide, and combinations thereof; and
wherein the first deposition is a perovskite material.

3. The method of claim 2, wherein the first 20 nm of depositions are made at a rate of 0.5 Å/second.

4. The method of claim 1, further comprising:
after making the first deposition, backfilling the deposition chamber with hydrogen iodide vapor and one or both of formamidine or methylamine;
making a second deposition on the substrate, the second deposition a perovskite material.

5. The method of claim 1, wherein:
the lead powder sample comprises lead (II) iodide; and
the method further comprising:
replacing leftover lead powder sample in the crucible with a salt precursor powder, the salt precursor comprising a salt selected from the group consisting of formamidinium iodide, methyl ammonium iodide, and combinations thereof;
sublimating the salt precursor;
making a second deposition on the substrate, the second deposition a perovskite material.

6. The method of claim 5, wherein the first 20 nm of depositions are made at a rate of 0.5 Å/second.

7. The method of claim 2, wherein backfilling occurs at a rate in the range of 2-100 sccm.

8. The method of claim 1, wherein the lead powder sample is a single crystal perovskite with the structure ABX₃.

9. A method for solvent-free perovskite deposition, comprising:
loading a lead salt precursor into a crucible;
loading a substrate into a sample holder;
reducing the pressure in the deposition chamber to at least 10⁻³ Torr;
applying a current to ionize the lead salt precursor;
backfilling the deposition chamber with the vapors of a second salt precursor; and
depositing a perovskite material on the substrate.

10. The method of claim 9, wherein:
the lead salt precursor comprises lead (II) iodide;
the second salt precursor comprises hydrogen iodide; and
the method further comprises backfilling the deposition chamber with the vapors of a salt selected from the group consisting of formamidinium iodide, methyl ammonium iodide, and combinations thereof.

11. The method of claim 9, wherein:
the lead salt precursor is ionized in the presence of a reactive gas;
the second salt precursor comprises a salt precursor selected from the group consisting of formamidinium iodide, methyl ammonium iodide, and combinations thereof.

12. The method of claim 11, wherein the reactive gas is selected from the group consisting of water, oxygen, nitrous oxide, ammonia, and nitrogen.

13. The method of claim 9, wherein the lead salt precursor comprises a salt selected from the group consisting of lead alkoxides, lead alkylamides, lead alkylsulfides, lead alkylselenides, plumbanes, and plumbylenes.

14. The method of claim 9, wherein the first 20 nm of depositions are made at a rate of 0.5 Å/second.

15. The method of claim 9, wherein the lead salt precursor comprises a salt selected from the group consisting of bis(1-dimethylaminio-2-methyl-2-propanolate)lead (II) (Pb(DMAMP)₂); bis(2,2,6,6-tetramethyl-3,5,heptanedionato)lead(II) (Pb(THD)₂); lead(II) hexafluoroacetylacetonate; plumbocene (PbCp₂); tetraethyllead(IV); bis[bis(trimethylsilyl)amido]lead(II); and rac-N²,N³-di-tert-butane-2,3-diamido lead (II).

16. A method for solvent-free perovskite deposition, comprising:
loading a lead salt precursor into a crucible;
loading a substrate in a sample holder;
reducing the pressure in the deposition chamber to between 5 Torr and 760 torr;
vaporizing the lead salt precursor;
performing metalorganic vapor phase epitaxy on the vapor;
backfilling the deposition chamber with the vapors of a second salt precursor; and
depositing, under an inert gas, a perovskite material on the substrate.

17. The method of claim 16, wherein the second salt precursor comprises a salt selected from the group consisting of formamidinium iodide, methyl ammonium iodide, and combinations thereof.

18. The method of claim 15, wherein:
the second salt precursor comprises hydrogen iodide; and
the method further comprises backfilling the deposition chamber with hydrogen iodide vapor.

19. The method of claim 16, vaporizing occurs by applying one of heat or a flow of electrons to the lead salt precursor.

20. The method of claim 16, wherein the lead salt precursor comprises a salt selected from the group consisting of lead alkoxides, lead alkylamides, lead alkylsulfides, lead alkylselenides, plumbanes, and plumbylenes.
